(19) United States
(12) Patent Application Publication
(10) Pub. No.: US 2019/0326498 A1
(43) Pub. Date: Oct. 24, 2019

(54) DEVICE FOR CONVERTING ELECTRICAL ENERGY INTO THERMAL ENERGY

(71) Applicant: GENTHERM GMBH, Odelzhausen (DE)

(72) Inventor: Rüdiger Spillner, Augsburg (DE)

(21) Appl. No.: 16/301,222

(22) PCT Filed: May 2, 2017
(86) PCT No.: PCT/DE2017/000119

§ 371 Date: Apr. 12, 2019

(30) Foreign Application Priority Data
May 19, 2016 (DE) 10 2016 006 063.8

(51) Int. Cl. H01L 35/32; H01L 35/30

(52) U.S. Cl. CPC H01L 35/32; H01L 35/30

(57) ABSTRACT

A device (20) for converting electrical energy into thermal energy is disclosed. The device (20) for converting electrical energy into thermal energy includes at least one layer (6) of multiple semiconductor elements (4), at least one enclosure (22), formed from at least two parts (26, 28), between whose oppositely situated broadside surfaces (26′, 28′) the at least one layer (6) of multiple semiconductor elements (4) is accommodated, wherein at least one of the two parts (26, 28) forming the enclosure (22) laterally protrudes beyond the layer (6) of multiple semiconductor elements (4), and wherein a portion (30) of the respective part (26, 28) protruding laterally beyond the layer (6) of multiple semiconductor elements (4) is a functional section (32).

The present invention relates to a device for converting electrical energy into thermal energy.

Devices for converting electrical energy into thermal energy are generally understood to mean so-called thermoelectrical devices (TED for short) or also electrothermal converters. These types of thermoelectrical devices may be operated in a heating or cooling mode, depending on the direction of current flow. When current flows through, a temperature difference is created on two opposite sides of the thermoelectrical device.

A number of such thermoelectrical devices are already known from the prior art. Typical thermoelectrical devices include a layer of multiple semiconductor elements. The layer of multiple semiconductor elements may be, for example, a layer of so-called thermoelectrical pellets (TE pellets for short), which are generally formed from semiconductor material in the form of p- and n-doped cubes.

The cubes made of semiconductor material are connected to one another in alternation on a top side and a bottom side by metal bridges. This respective connection results in a series connection of the semiconductor elements, as the result of which the supplied current flows through each of the cubes. Depending on the current intensity and current direction, the connection points on one side surface cool, while the connection points on the other side surface heat. Heat may thus be pumped from one side surface to the other side surface by means of the current, resulting in a temperature difference between the side surfaces.

The layer of semiconductor elements is often soldered or attached in some other way between parts, forming an enclosure, in the form of two layers of ceramic or copper plates, since in particular ceramic and copper have a high heat conductivity. The top side and bottom side parts of the enclosure may subsequently be coupled to other components, such as a fluid circuit, by means of a solder, adhesive, lubricant, or thermal film connection, for example. However, a problem with such known units is that the stated top side and bottom side parts are not designed to allow fixing or a flexible or sealing fastening of the thermoelectrical device, since in particular the parts of the enclosure made of ceramic or copper plates are very rigid, dimensionally stable parts.

Even when such a thermoelectrical device is coupled to a fluid circuit, for example, distinct disadvantages result from ceramic or copper plates as a component of the enclosure of the layer of multiple semiconductor elements. In many known devices for converting electrical energy into thermal energy, the layer of semiconductor elements is bordered between ceramic or copper plates, the semiconductor elements being attached between the ceramic or copper plates via, for example, a layer of solder material, adhesive, lubricant, thermal film, etc. The device for converting electrical energy into thermal energy may be coupled to a fluid circuit via a part of the enclosure. However, in this design it is possible that a number of thermal resistances may result for a heat flow in the direction of the fluid circuit. Thus, it has been shown that considerable heat losses occur for a heat flow of a medium. In particular for liquids or gaseous fluids, deficient or poor sealing of the device may be accompanied by undesirable fluid losses.

The object of the invention, therefore, is to provide a device for converting electrical energy into thermal energy, which at least partially eliminates the above-stated disadvantages of the prior art.

The above object is achieved by a device for converting electrical energy into thermal energy which includes the features in claim 1. Further advantageous embodiments are described by the subclaims.

A device according to the invention for converting electrical energy into thermal energy includes at least one layer of multiple semiconductor elements, and an enclosure, formed from at least two parts, between whose oppositely situated broadside surfaces the at least one layer of multiple semiconductor elements is accommodated. At least one of the two parts forming the enclosure laterally protrudes beyond the layer of multiple semiconductor elements. In addition, a portion of the respective part laterally protruding beyond the layer of multiple semiconductor elements is designed as a functional section.

In a design according to the invention of the device for converting electrical energy into thermal energy, it may also be provided that the functional section of the at least one part of the two parts forming the enclosure has an arched structure, at least in areas. For the case that the at least one part forming a functional section is situated directly adjacent to a fluid, the functional section in the area of the arched structure may cooperate with an element that encloses the fluid, as a sealing unit in order to seal off the layer of multiple semiconductor elements from the fluid. The functional section of the at least one part of the two parts forming the enclosure may thus at the same time act as a seal. A seal may be advantageous in particular when the device for converting electrical energy into thermal energy is coupled to an element that encloses a gaseous or liquid fluid, in order to prevent losses of the fluid due to unintentional leakage of the fluid from the element enclosing the fluid through gaps or cracks between the device for converting electrical energy into thermal energy, situated on the element enclosing the fluid, and the element enclosing the fluid. The functional section may be designed with depressions and/or bulges or may form depressions and/or bulges in order to provide sealing properties.

It is advantageous when the arched structure of the functional section provided for sealing extends around an area of the layer of multiple semiconductor elements, at a certain distance therefrom, and in cooperation with the element enclosing the fluid forms a sealing ring, so that the layer of multiple semiconductor elements is sealed off from the fluid.

In addition, the functional section may have greater rigidity than other areas of the part. The greater rigidity of the part may be brought about, for example, by material having a reinforced and/or stiffened design in the area of the functional section of the part. The reinforcement of the functional section of the part may be provided, for example, by an increased cross section of the part in the area of the functional section compared to other areas of the part. Furthermore, it is also conceivable to reinforce the part in the area of the functional section by adding other materials and/or reinforcing or stiffening elements. Stability of the at least one part of the two parts forming the enclosure may be improved by the reinforcement and/or stiffening. Unintended bending or bursting of solder joints, for example, between individual parts of the device for converting electrical energy into thermal energy may be prevented in this way.

The functional section may be designed, using standard methods, in such a way that the accommodation of sealants such as O-rings, sealing compounds such as silicone, or solder or adhesive is made possible or simplified. In addition, the functional surface may be designed in such a way that integral bonding (welding, for example) is providable.

In addition, the thermal conductivity between the functional section and the semiconductor elements may be meaningfully influenced, for example, via spacing, wall thickness, or ribbing or similar structures. Increasing the heat conduction may, for example, improve the heat exchange with the body that is contacted at the functional section. On the other hand, reducing the heat conductivity, for example for joining processes with high heat input (welding, soldering), may prevent overheating of the TED.

Furthermore, it is conceivable for the functional section to have a reversibly elastically deformable design, at least in areas. The functional section may have a resiliently flexible design due to its reversible elastic deformability, at least in areas. Elastic properties of the functional section possibly brought about in this way may be meaningful in several respects. For example, when the device for converting electrical energy into thermal energy cooperates with an element enclosing fluid, pressure fluctuations with regard to the fluid may occur. The pressure fluctuations of the fluid may also change a pressure that acts on the device for converting electrical energy into thermal energy, in particular the part of the enclosure that may possibly be in thermal contact with the fluid. Due to the reversible elastic deformability of the functional section, pressure fluctuations may be balanced to a certain extent, for example to avoid damage to the layer of multiple semiconductor elements, or solder joints between individual parts of the device for converting electrical energy into thermal energy. In addition, the elastic property may be utilized in a targeted manner to provide a contact force between the TED and a surface to be temperature-controlled, in that the functional surface is deflected from the unloaded normal position, in the direction of force. This may occur, for example, when the functional surface is being screwed to the surface to be temperature-controlled. In some cases it is conceivable for the at least one layer of multiple semiconductor elements to be situated at a certain distance from, and without direct contact with, the at least one second part of the enclosure formed from at least two parts. For example, due to the reversible elastic deformability of the functional section of the at least one part that includes the functional section, a deflection may be used to establish contact between the at least one layer of multiple semiconductor elements and the at least one second part of the enclosure. A targeted transmission of heat energy between the parts of the device for converting electrical energy into thermal energy may thus be provided or avoided in order to obtain a desired transmission of heat energy or avoid same.

In conceivable embodiments, the functional section may have at least one opening that is designed for receiving a fastening element. As a result of the at least one opening, the at least one part of the at least two parts forming the enclosure, which has the functional section, or the entire device for converting electrical energy into thermal energy may be easily and durably connected to an element enclosing a fluid or attached to an element enclosing a fluid, by means of fastening elements such as screws. If two of the at least two parts forming the enclosure each have openings, it is also possible to brace the components of the device for converting electrical energy into thermal energy, such as the layer of multiple semiconductor elements, between the parts forming the enclosure. In particular, it is meaningful when the openings are situated in convexly curved edge or corner areas of the part forming the functional section. Openings situated outside the arched structure of the functional section are advantageous, in particular when cooperation of the functional section having an arched structure is provided, and the element enclosing the fluid is designed as a sealing unit. As the result of fixing the device for converting electrical energy into thermal energy through the openings by means of fastening elements, a good sealing effect results by pressing the arched structure of the functional section against an element that seals off the fluid, so that escape of fluid from the element enclosing the fluid may be prevented.

Moreover, an upper broadside surface of the at least one part forming the functional section, the upper broadside surface facing away from the at least one layer of multiple semiconductor elements, may form a segment of a channel for fluid.

It is also conceivable that the at least one part that forms the functional section includes a heat exchange-promoting structure on the upper broadside surface in the area of the segment.

In addition, the at least one part that forms the functional section may include an elastic layer, at least in part, on the upper broadside surface in the area of the segment. Furthermore, a broadside surface of at least one of the at least two parts forming the enclosure, facing in the direction of the at least one layer of multiple semiconductor elements, may be provided with a heat exchange-promoting element.

Moreover, embodiments are conceivable in which the enclosure formed from at least two parts is designed for accommodating at least two spaced-apart layers of multiple semiconductor elements.

In addition, each of the at least two parts may laterally protrude beyond the at least one layer of multiple semiconductor elements. The portions of the at least two parts that laterally protrude beyond the layer of multiple semiconductor elements may be designed as a functional section.

It is evident that at least the functional section, at least at the locations contacting the other bodies or fluids, may be coated, treated, or passivated in such a way that electrical or thermal conduction may be promoted or largely prevented, or that corrosion protection is achieved. Common methods include, for example, anodizing, tin plating, coating with aluminum oxide, application of nitrile rubber, etc.

It may be advantageous for the protruding area or the functional section (or parts thereof) to have material compositions that are different from one another or from the enclosure. Targeted properties such as areas of differing elasticity or heat conductivity may be provided in this way. In addition, a wide range of different production and joining processes may be utilized to provide the properties according to the invention.

The invention further relates to a vehicle seat, a vehicle steering wheel, a battery, or a battery housing in the vehicle, a temperature-controllable beverage holder for vehicles, as well as a heat exchanger, heat store, or heat transfer unit, that includes at least one device for converting electrical energy into thermal energy according to an embodiment from the above description.

Exemplary embodiments of the invention and their advantages are explained in greater detail with reference to the appended figures. The proportions of the individual elements with respect to one another in the figures do not always correspond to the actual proportions, since some shapes are simplified, and other shapes are illustrated on a larger scale than other elements for better clarity. Identical reference numerals are used for similar or functionally equivalent elements of the invention. In addition, for the sake of clarity, only reference numerals that are necessary for describing the particular figure are illustrated in the individual figures. The illustrated embodiments merely represent examples of how the device according to the invention may be configured, and do not constitute a definitive delimitation.

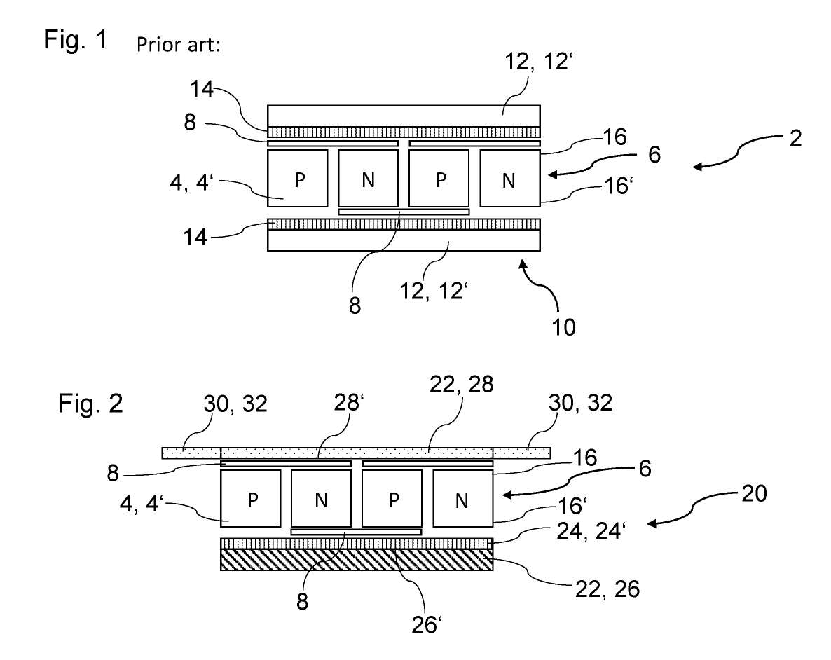

FIG. 1 shows a schematic view of a device for converting electrical energy into thermal energy, as already known from the prior art;

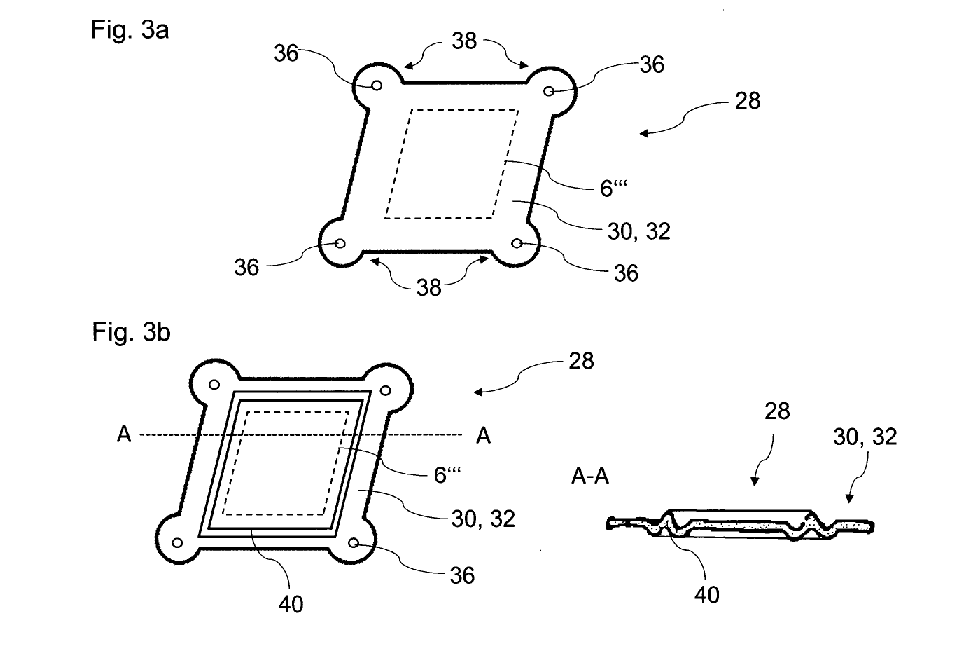

FIG. 2 shows a schematic view of one embodiment of a device according to the invention for converting electrical energy into thermal energy;

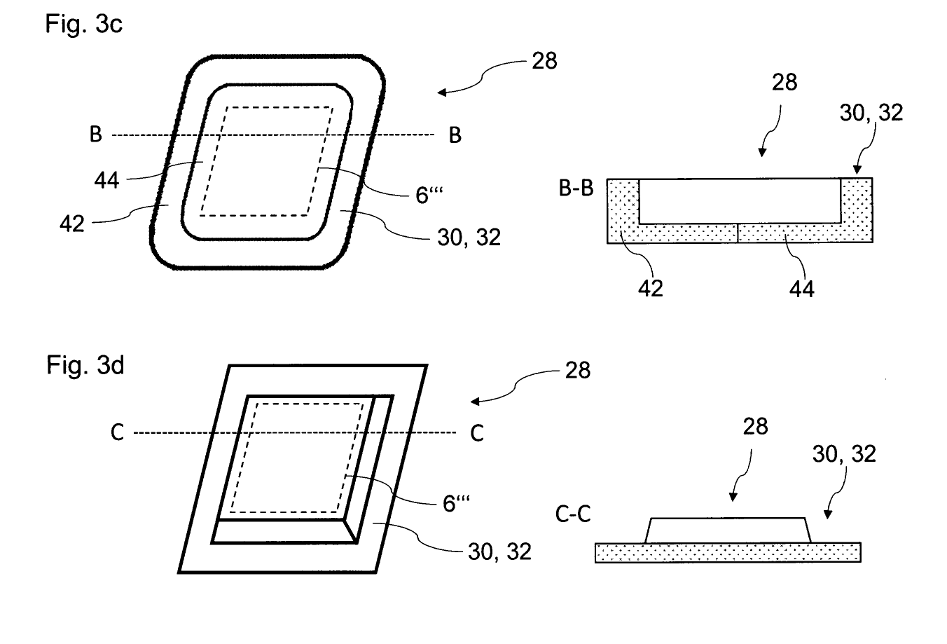

FIGS. 3a, 3b, 3c, 3d, and 3e show a schematic view of one conceivable design of one of the parts forming the enclosure, which laterally protrudes beyond the layer of multiple semiconductor elements;

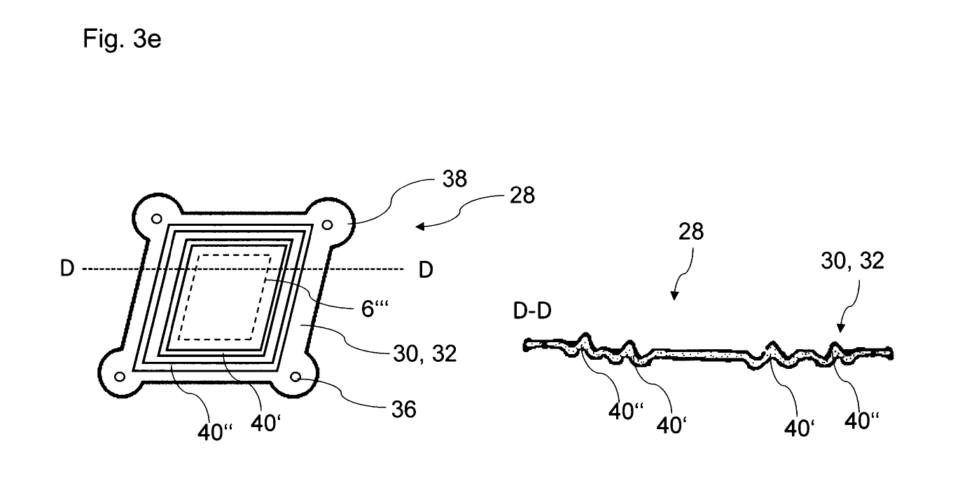

FIG. 4 shows a schematic view of one embodiment of a device according to the invention for converting electrical energy into thermal energy;

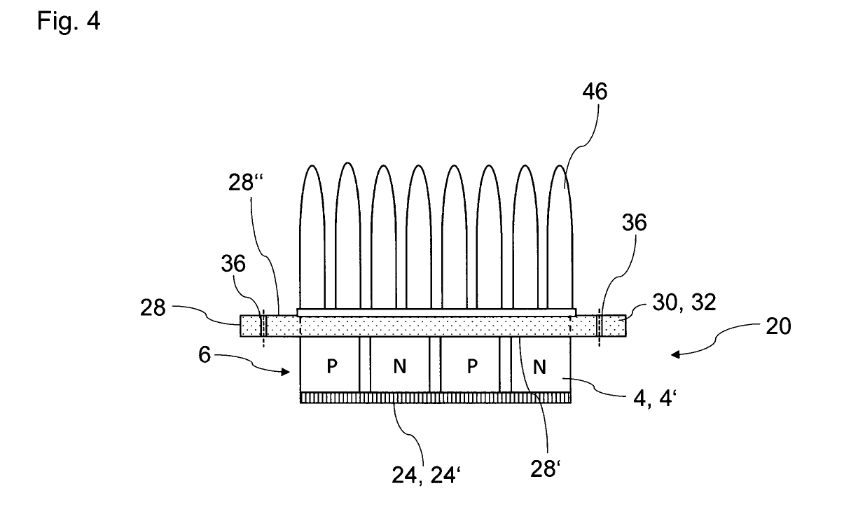

FIG. 5 shows a schematic view of one embodiment of a device according to the invention for converting electrical energy into thermal energy, which in the embodiment shown in FIG. 5 is coupled to a fluid circuit or includes a fluid circuit;

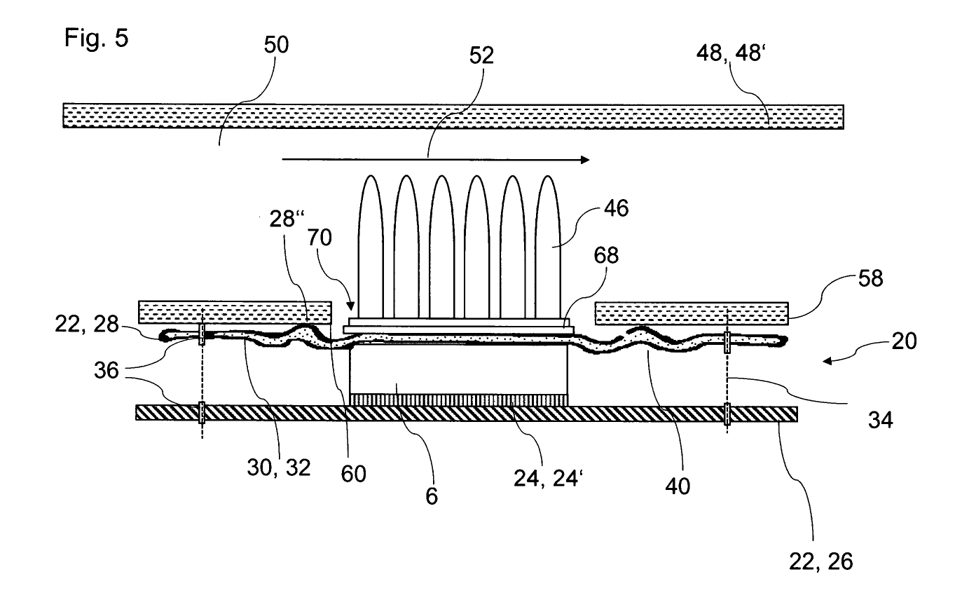

FIG. 6 shows another conceivable embodiment of a device according to the invention for converting electrical energy into thermal energy;

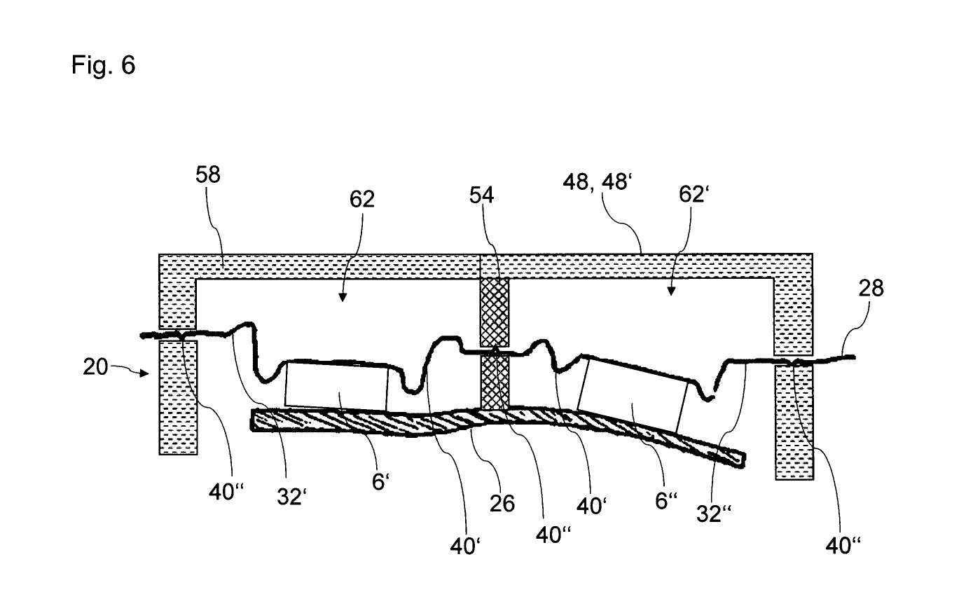

FIG. 7 shows another embodiment of a device according to the invention for converting electrical energy into thermal energy;

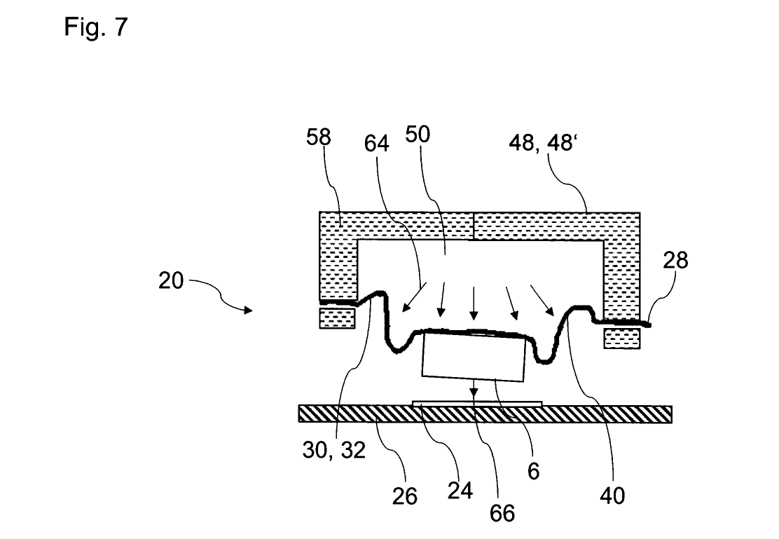

FIG. 8 shows another embodiment of a device according to the invention for converting electrical energy into thermal energy;

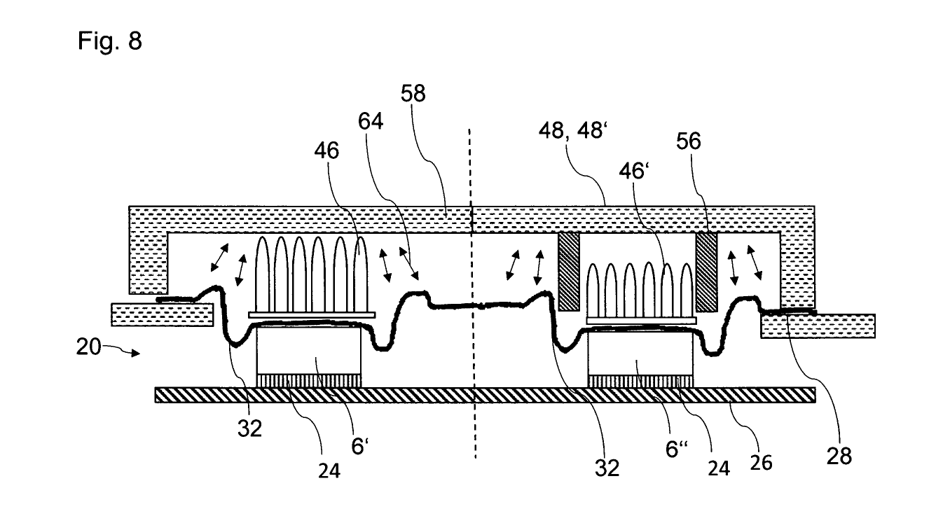

FIGS. 9a, 9b show another embodiment of a device according to the invention for converting electrical energy into thermal energy;

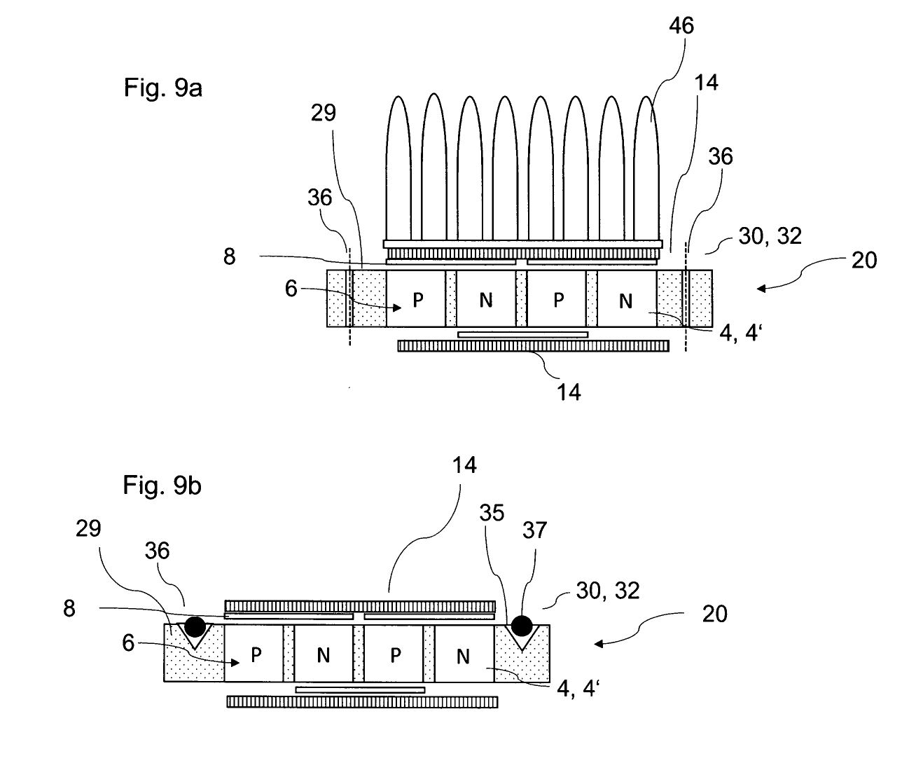

FIG. 10 shows another embodiment of a device according to the invention for converting electrical energy into thermal energy; and

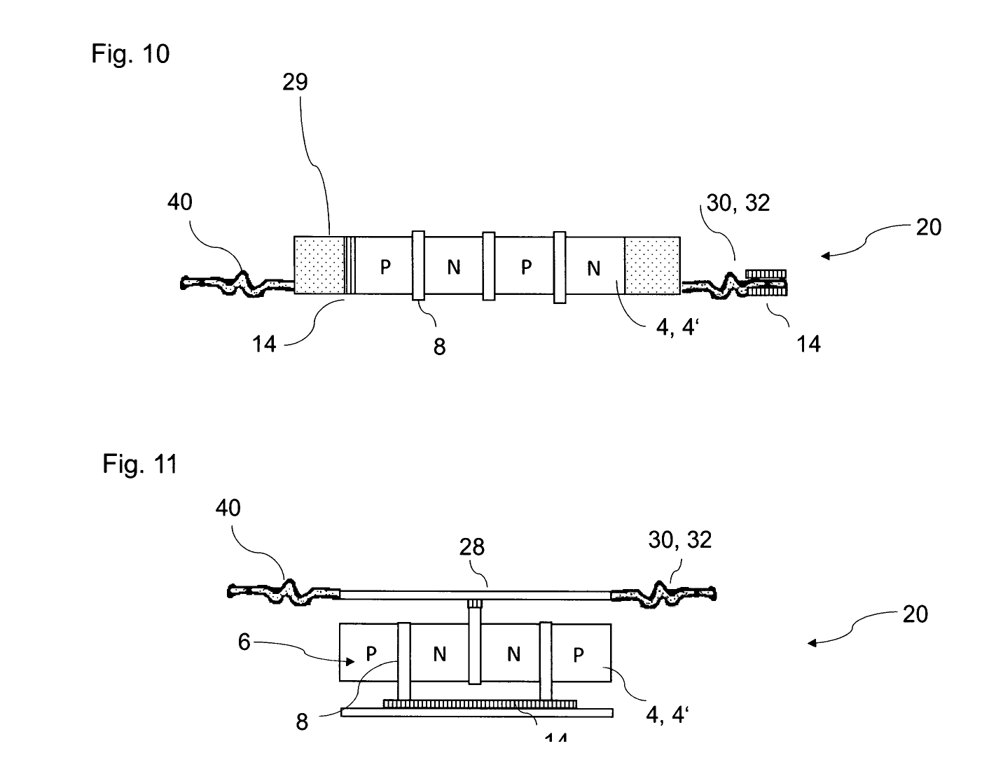

FIG. 11 shows another embodiment of a device according to the invention for converting electrical energy into thermal energy.

FIG. 1 shows a device 2 for converting electrical energy into thermal energy according to the known prior art. The device 2 for converting electrical energy into thermal energy includes a layer 6 of multiple semiconductor elements 4. The semiconductor elements 4 are so-called cuboidal TE pellets 4′ that are p- and n-doped in alternation. The cuboidal TE pellets 4′ are coupled to one another in alternation on the top and bottom sides 16 and 16′ by metal bridges 8, so that in each case two differently doped TE pellets 4′ are connected to one another. The layer 6 of multiple TE pellets 4′ is incorporated between two parts 12, in the form of ceramic or copper plates 12′, that form an enclosure 10. The layer 6 of multiple TE pellets 4′ is incorporated between the parts 12 that form an enclosure 10 by means of a heat exchange-promoting element 14, for example in the form of a soldered, adhesive, printed, lubricant, or thermal film layer.

FIG. 2 shows one embodiment of a device 20 according to the invention for converting electrical energy into thermal energy. The device 20 for converting electrical energy into thermal energy includes a layer 6 of multiple semiconductor elements 4. The semiconductor elements 4 are cuboidal TE pellets 4′ that are p- and n-doped in alternation. The cuboidal TE pellets 4′ are connected to one another in alternation on the top and bottom sides 16 and 16′ by metal bridges 8, so that in each case two differently doped TE pellets 4′ are connected to one another. The layer 6 of multiple semiconductor elements 4 is situated between broadside surfaces 26′ and 28′ of an enclosure 22 formed from at least two parts 26 and 28. The part 28 of the enclosure 22 protrudes beyond the layer 6 with a portion as indicated by reference numeral 30. The laterally protruding portion 30 of the part 28 is designed as a functional section 32. It is apparent in FIG. 2 that the part 28 of the enclosure 22 that includes the functional section 32 has a reduced cross section compared to the part 26. A heat exchange-promoting element 24 is situated between the broadside surface 26′ and the layer 6 of multiple semiconductor elements 4. The heat exchange-promoting element 24 may be a thermal film or a solder joint 24′, for example, which in addition to heat exchange-promoting properties may also provide for fixing of the layer 6 of multiple semiconductor elements 4 on the broadside surface 26′ of the part 26.

FIGS. 3a through 3e show various embodiments of a part 28 according to the invention that includes a functional section 32. The possibility for mixed forms of the various embodiments of the functional section 32 is not excluded. As mentioned above, the part 28 protrudes beyond the layer 6 of multiple semiconductor elements 4. The laterally protruding portion of the part 28 is denoted by reference numeral 30. The region of the lateral extension of the layer 6 of multiple semiconductor elements 4 is indicated in each case by the dashed line 6′″ in FIGS. 3a through 3e. The functional section 32 of the part 28 according to FIG. 3a has multiple openings 36 for receiving fastening elements, for example in the form of screws, for fastening the device 20 for converting electrical energy into thermal energy or the part 28.

The openings 36 are each situated in convexly curved edge or corner areas 38 of the functional section 32 of the part 28, since such a type of arrangement of the openings 36 allows a stable fastening option for the device 20 for converting electrical energy into thermal energy or for the part 28. In addition, in the embodiment variant in FIG. 3b the functional section 32 of the part 28 includes convexly curved edge or corner areas 38 that have openings 36 in each case. Furthermore, the functional section 32 has an arched structure 40 that encloses and is spaced apart from the region 6m of the layer 6 of multiple semiconductor elements 4. The arched structure 40 is formed by depressions and elevations in the material of the part 28, as is apparent in particular in the sectional illustration A-A in FIG. 3b. A sealing unit may be provided by the arched structure 40. In addition, the arched structure 40 or the part 28 in the area of the arched structure 40 may be reversibly elastically deformable.

According to the embodiment of the functional section 32 of the part 28 in FIG. 3c, at least areas 42 of the functional section 32 have greater rigidity than other areas 44 of the part 28. The same as for the arched structure 40 in FIG. 3b, the area 42 of greater rigidity may enclose the region 6′″ of the layer 6 of multiple semiconductor elements 4 at a distance therefrom. The greater rigidity of the area 42 may be provided, for example, by reinforcement of the material of the part 28. The greater rigidity of the area 42 of the part 28 provides an overall high stability of the part 28, resulting in less risk of damage to solder joints 24′ (see FIG. 2) or to the layer 6 of multiple semiconductor elements 4. The embodiment in FIG. 3d has a reinforced area that covers the region 6′″ of the layer 6 of multiple semiconductor elements and thus protects from damage, for example.

FIG. 3e shows one embodiment of the functional section 32 of the part 28 in a previously mentioned mixed form. The part 28 once again has convexly curved edge or corner areas 38. The functional section 32 has openings 36 in each of these edge or corner areas 38.

In addition, the functional section 32 of the part 28 includes a first arched structure 40′ having a reversibly elastically deformable design, at least in areas. Furthermore, the functional section 32 includes a second arched structure 40″ which in cooperation with an element 58 that encloses a fluid forms a sealing unit. The first arched structure 40′ and the second arched structure 40″ surround the layer 6 of multiple semiconductor elements 4 or its region 6′″ at a certain distance therefrom. The sectional illustration D-D depicts once again the first and second arched structures 40′ and 40″ of the functional section 32 of the part 28.

FIG. 4 illustrates another embodiment of a device 20 according to the invention for converting electrical energy into thermal energy. Only the part 28 of the enclosure 22 that is coupled to the layer 6 of multiple semiconductor elements 4 on the lower broadside surface 28′ is depicted. Openings 36 are provided in the functional section 32 on the laterally protruding portion 30 of the part 28. The part 28 is provided with a heat exchange-promoting structure 46 on the upper broadside surface 28″ of the part 28. As shown in FIG. 5, when the device 20 for converting electrical energy into thermal energy is coupled to an element that encloses a fluid 50, for example a wall 58 of a channel for fluid 48 or a fluid circuit 48′, the heat exchange-promoting structure 46 may be in thermally conductive contact with a fluid 50 of the channel for fluid 48 or the fluid circuit 48′. The fluid 50 may be a liquid or gaseous fluid.

In the embodiment variant of the device 20 for converting electrical energy into thermal energy according to FIG. 5, the functional section 32 of the part 28 may have an arched structure 40 next to the openings 36. The part 26 of the enclosure 22 may also be provided with openings 36, so that fastening elements 34 may be guided through the openings 36 in the part 28 and in the part 26. In this type of arrangement, the heat exchange-promoting structure 46 is situated in the flow of the fluid 50, whose direction of fluid flow is indicated by the arrow 52, thus allowing promotion of the heat exchange. In addition, an elastic layer 68 may be provided in addition to the heat exchange-promoting structure 46 or instead of the heat exchange-promoting structure 46. In the connection of the device 20 for converting electrical energy into thermal energy to the channel for fluid 48, the part 28 that forms the functional section 32 is situated directly adjacent to the fluid 50 of the channel for fluid 48. This may be provided, for example, by a recess 60 in the wall 58 of the channel for fluid 48, in which area of the recess 60 the fluid 50 is thus in direct contact with a segment 70 of the upper broadside surface 28″ of the part 28. In this area of the recess or the connection of the part 28 that includes the functional section 32 to the channel for fluid 48, the part 28 itself accordingly partially forms the channel 48. Fastening of the device 20 for converting electrical energy into thermal energy to the wall of the channel for fluid 48 may take place by means of fastening elements 34 that are guided through the openings 36. Due to the arched structure 40 of the functional section 32, fixing of the device 20 for converting electrical energy into thermal energy by means of the fastening elements 34 results in a sealing unit. It is thus possible to seal off the layer 6 of multiple semiconductor elements 4 from the fluid 50.

FIG. 6 shows another embodiment of a device 20 according to the invention for converting electrical energy into thermal energy. The part 28 of the enclosure 22 is designed in such a way that a connection of a first layer 6′ and a second layer 6″, each made up of multiple semiconductor elements 4, may be made possible. The part 28 for accommodating the first and second layers 6′ and 6″, each made up of multiple semiconductor elements 4, is thus formed. The channel for fluid 48, to which the device 20 for converting electrical energy into thermal energy is connected, is divided into a first and second channel segment 62 and 62′ by means of a partition wall 54, so that the first layer 6′ of multiple semiconductor elements 4 is situated in the first channel segment 62, and the second layer 6″ of multiple semiconductor elements 4 is situated in the second channel segment 62′. The part 28 includes independent functional sections 32′ and 32″ in the area of the first and second layers 6′ and 6″, respectively.

The functional sections 32′ and 32″ each have a first arched structure 40′ and a second arched structure 40″. The first arched structure 40′ is situated in the area of the layer 6 and 6″ of multiple semiconductor elements 4′. The functional sections 32′ and 32″ have a reversibly elastically deformable design in the area of the arched structure 40′ and 40″, respectively, thus allowing resiliency of the part 28. This reversible elastic deformability of the functional sections 32′ and 32″ is advantageous when the part 26 has a nonflat or nonlinear cross section, since a stable, secure arrangement of the layers 6′ and 6″ of multiple semiconductor elements 4 is thus made possible by the reversible elastic deformability. The functional sections 32′ and 32″ cooperate with the wall 58 of the channel for fluid 48 or the partition wall 54 in the area of the second arched structure 40″, thus forming a sealing unit in each case. The layers 6′ and 6″ of multiple semiconductor elements 4 are thus sealed off from the fluid. The arched structures 40″ of the first and second functional section 32′ and 32″ may be designed as a shared arched structure 40″ in the area of the partition wall 54.

Reversible elastic deformability of the part 28 in the area of the arched structure 40 is also indicated in FIG. 7. A pressure change with regard to the fluid 50 in the fluid circuit 48′ is symbolized by the arrows 64, the pressure change acting on the part 28 in such a way that a displacement of the layer 6 of multiple semiconductor elements 4 in the direction of the heat exchange-promoting element 24, as illustrated by the arrow 66, takes place due to the reversible elastic deformability of the arched structure 40. A targeted pressure change of the fluid 50 may be used in particular to control contact, to be established or avoided, with the heat exchange-promoting element 24 in order to obtain a desired transmission of heat energy or avoid same. In addition, the reversible elastic deformability of the functional section 32 may prevent damage to the layer 6 of multiple semiconductor elements 4 or to solder joints that are present.

FIG. 8 shows another embodiment of a device 20 according to the invention for converting electrical energy into thermal energy. To limit the deflection of the part 28 in the direction of the wall 58 of the channel for fluid 48, for example to avoid damage, the heat exchange-promoting structure 46 may be designed in such a way that it abuts against the wall 58 of the channel for fluid 48 when there is a given pressure change of the fluid 50, symbolized by the arrows 64, thus preventing further deformation of the part 28. As another option, limiting elements 56 which limit the deformation of the part 28 may be mounted in the area of the layer 6″ of multiple semiconductor elements 4. The heat exchange-promoting structure 46′ may have smaller dimensions than the heat exchange-promoting structure 46. At a given pressure, the limiting elements 56 abut against the part 28 and thus prevent further deformation of the part 28 or of the functional section 32.

FIGS. 9a and 9b show further embodiments of a device 20 according to the invention for converting electrical energy into thermal energy. The design and function are largely analogous to FIG. 4, with the essential difference that the enclosure 29 has a one-piece design, encloses the semiconductor element 4 at each of four surfaces, and is preferably made of an insulating material. The enclosure 29 encloses neither the metal bridges 8 nor the insulating layers 14. This type of design for a TED is already known. According to the invention, the enclosure 29 is laterally extended 30 and has a functional section 32. In FIG. 9a, openings 36 are provided that allow fastening. In FIG. 9b, a structure 35 for accommodating a sealant 37 is provided. O-rings, solder, adhesive, or silicone compound, for example, may be used as sealant.

FIG. 10 shows another embodiment of a device 20 according to the invention for converting electrical energy into thermal energy. In this design, the semiconductor elements 4 are situated in a stack that is connected via metal bridges. This type of design is already known from the prior art. According to the invention, a laterally extended enclosure 29 is provided, and is equipped with a functional section 32 in the protruding area 30. The functional section 32 has a convex curvature here which functions as a circumferential seal.

FIG. 11 shows another embodiment of a device 20 according to the invention for converting electrical energy into thermal energy. The semiconductor elements are designed as a stack. The heat is conducted from the semiconductor elements 4 by means of the metal bridges 8, via an insulating layer 14, to an enclosure 28 that essentially covers one side of the semiconductor elements. Such a design is already known from the prior art. According to the invention, the enclosure 28 has a laterally protruding portion 30, and at that location is provided with a functional area 32. The functional area has a convex curvature here which is suitable for providing a circumferential seal or compensating for thermal expansions.

The invention has been described with reference to one preferred embodiment. However, it is conceivable for those skilled in the art to make use of modifications or changes to the invention without departing from the scope of protection of the claims set forth below.

### LIST OF REFERENCE NUMERALS

2 device for converting electrical energy into thermal energy (prior art)
4, 4′ semiconductor elements, TE pellets
6, 6′, 6″, 6′″ layer, first layer, second layer, region of the layer
8 metal bridges
10 enclosure
12, 12′ part, ceramic or copper plate
14 heat exchange-promoting element
16, 16′ top side, bottom side
20 device for converting electrical energy into thermal energy
22 enclosure
24, 24′ heat exchange-promoting element, thermal film/solder joints
26, 26′ part, broadside surface
28, 28′, 28″ part, lower broadside surface, upper broadside surface
29 one-piece enclosure
30 laterally protruding portion
32, 32′, 32″ functional section, first functional section, second functional section
34 fastening element
35 sealant receptacle
36 opening
38 edge or corner area
40, 40′, 40″ arched structure, first arched structure, second arched structure
42 area with greater rigidity
44 area with lesser rigidity
46 heat exchange-promoting structure
48, 48′ channel for fluid, fluid circuit
50 fluid
52 direction of fluid flow
54 partition wall
56 limiting elements
58 element enclosing fluid, wall of the channel for fluid/of the fluid circuit
60 recess
62, 62′ first channel segment, second channel segment
64 pressure change
66 pressure change
68 elastic layer
70 segment

1. A device for converting electrical energy into thermal energy, comprising:
at least one layer of multiple semiconductor elements and
an enclosure, formed from at least two parts, between whose oppositely situated broadside surfaces the at least one layer of multiple semiconductor elements is accommodated,
wherein
at least one of the two parts forming the enclosure laterally protrudes beyond the layer of multiple semiconductor elements,
and
wherein
a portion of the respective part protrudes laterally beyond the at least one layer of multiple semiconductor elements is designed as a functional section.

2. The device for converting electrical energy into thermal energy according to claim 1, wherein the functional section has an arched structure, at least in areas.

3. The device for converting electrical energy into thermal energy according to claim 2, wherein the at least one part forming a functional section is situated directly adjacent to a fluid, and wherein the functional section in the area of the arched structure cooperates with an element that encloses the fluid, so that the layer of multiple semiconductor elements is sealed off from the fluid.

4. The device for converting electrical energy into thermal energy according to claim 1, wherein the functional section has greater rigidity than other areas of the part.

5. The device for converting electrical energy into thermal energy according to claim 1, wherein the functional section has a reversibly elastically deformable design, at least in areas.

6. The device for converting electrical energy into thermal energy according to claim 1, wherein the functional section has at least one opening that is designed for receiving a fastening element.

7. The device for converting electrical energy into thermal energy according to claim 1, in which an upper broadside surface of the at least one part forming the functional section, the upper broadside surface facing away from the at least one layer of multiple semiconductor elements, forms a segment of a channel for fluid.

8. The device for converting electrical energy into thermal energy according to claim 7, wherein the at least one part that forms the functional section includes a heat exchange-promoting structure on the upper broadside surface in the area of the segment.

9. The device for converting electrical energy into thermal energy according to claim 7, wherein the at least one part that forms the functional section includes an elastic layer, at least in part, on the upper broadside surface in the area of the segment.

10. The device according to claim 1, in which a broadside surface of at least one of the at least two parts forming the enclosure, facing in the direction of the at least one layer of multiple semiconductor elements, is provided with a heat exchange-promoting element.

11. The device for converting electrical energy into thermal energy according to claim 1, wherein the enclosure formed from at least two parts is designed for accommodating at least two spaced-apart layers of multiple semiconductor elements.

12. The device for converting electrical energy into thermal energy according to claim 1, wherein each of the at least two parts laterally protrudes beyond the at least one layer of multiple semiconductor elements, and wherein the portions of the at least two parts that laterally protrude beyond the at least one layer of multiple semiconductor elements are each designed as a functional section.

13. The device according to claim 1, wherein the enclosure is provided as only one piece or on one side.

14. The device according to claim 13, wherein the one-piece enclosure encloses the semiconductor elements on at least one side.

15. A vehicle seat, vehicle steering wheel, battery, or battery housing in a vehicle, temperature-controllable beverage holder for vehicles, as well as a heat exchanger, heat store, or heat transfer unit, that includes at least one device for converting electrical energy into thermal energy according to claim 1.

16. A thermoelectrical generator or part thereof that encompasses claim 1.
